(19) United States
(12) Patent Application Publication
(10) Pub. No.: US 2023/0163110 A1
(43) Pub. Date: May 25, 2023

(54) DISPLAY APPARATUS

(71) Applicant: AUO Corporation, Hsinchu (TW)

(72) Inventors: Sheng-Kai Lin, Hsinchu (TW); Chung-Chan Liu, Hsinchu (TW)

(73) Assignee: AUO Corporation, Hsinchu (TW)

(21) Appl. No.: 17/991,842

(22) Filed: Nov. 21, 2022

(30) Foreign Application Priority Data
Nov. 25, 2021 (TW) 110144075

(51) Int. Cl. H01L 25/075; H01L 33/62; H01L 33/50; H01L 33/38

(52) U.S. Cl. CPC H01L 25/0753; H01L 33/62; H01L 33/505; H01L 33/382

(57) ABSTRACT

A display apparatus includes a driving backplane and light-emitting elements. The driving backplane includes a substrate, pixel driving circuits, and a conductive layer. The conductive layer has conductive patterns respectively electrically connected to the pixel driving circuits. The light-emitting elements are respectively electrically connected to the conductive patterns. The light-emitting elements includes a first light-emitting element and a second light-emitting element. The conductive patterns includes a first conductive pattern and a second conductive pattern respectively electrically connected to the first light-emitting element and the second light-emitting element. A first distance is between a top surface of the first light emitting element and the first conductive pattern. A second distance is between a top surface of the second light emitting element and the second conductive pattern. The second distance is greater than the first distance.

### CROSS-REFERENCE TO RELATED APPLICATION

This application claims the priority benefit of Taiwanese application no. 110144075, filed on Nov. 25, 2021. The entirety of the above-mentioned patent application is hereby incorporated by reference herein and made a part of this specification.

### BACKGROUND

### Technical Field

The disclosure relates to an optoelectronic device. In particular, the disclosure relates to a display apparatus.

### Description of Related Art

With the evolution of display technology, thinned display apparatuses with high resolution are favored by the mainstream market. In recent years, due to technological breakthrough in the process of light-emitting diode (LED) elements, a micro-LED display or a millimeter-scale LED display that can be manufactured by arranging LED elements into an array and need not be provided with a liquid crystal layer or a color filter has been developed, and can further reduce a thickness of the display apparatus. In addition, compared to an organic LED display, the micro-LED display is more power-saving and has a longer lifespan.

Currently during the process of manufacturing the micro-LED display, a large number of LED elements need to be transferred to a driving backplane through mass transfer. Some of the LED elements transferred to the driving backplane may be abnormal and need to be removed. Then, LED elements for repair are transferred to the driving backplane to complete repair. However, during repair, a transfer element that picks up the LED elements for repair may damage normal LED elements that have been transferred to the driving backplane, affecting the yield of the micro-LED display.

### SUMMARY

The disclosure provides a display apparatus, for which repair is relatively easy.

The disclosure provides another display apparatus, for which is repair also relatively easy.

According to an embodiment of the disclosure, a display apparatus includes a driving backplane and a plurality of light-emitting elements. The driving backplane includes a substrate, a plurality of pixel driving circuits, and a conductive layer. The pixel driving circuits are disposed on the substrate. The conductive layer has a plurality of conductive patterns. The conductive patterns are respectively electrically connected to the pixel driving circuits. The light-emitting elements are respectively electrically connected to the conductive patterns. Each of the light-emitting elements has a top surface facing away from the substrate. The light-emitting elements include a first light-emitting element and a second light-emitting element. The conductive patterns include a first conductive pattern and a second conductive pattern. The first light-emitting element and the second light-emitting element are respectively electrically connected to the first conductive pattern and the second conductive pattern. A first distance is between the top surface of the first light-emitting element and the first conductive pattern. A second distance is between the top surface of the second light-emitting element and the second conductive pattern. The second distance is greater than the first distance.

According to another embodiment of the disclosure, a display apparatus includes a driving backplane and a plurality of light-emitting elements. The driving backplane includes a substrate, a plurality of pixel driving circuits, and a pad layer. The pixel driving circuits are disposed on the substrate. The pad layer has a plurality of pad sets. The pad sets are respectively electrically connected to the pixel driving circuits. The light-emitting elements are respectively electrically connected to the pad sets. The light-emitting elements include a first light-emitting element and a second light-emitting element. The pad sets include a first pad set and a second pad set. The first light-emitting element and the second light-emitting element are respectively electrically connected to the first pad set and the second pad set. A distance between at least one pad of the second pad set and the substrate is greater than a distance between at least one pad of the first pad set and the substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1C show a repair process of a display apparatus of an embodiment of the disclosure.

FIG. 2A to FIG. 2C show a repair process of a display apparatus of an embodiment of the disclosure.

FIG. 3A to FIG. 3C show a repair process of a display apparatus of an embodiment of the disclosure.

FIG. 4A to FIG. 4C show a repair process of a display apparatus of an embodiment of the disclosure.

FIG. 5A to FIG. 5C show a repair process of a display apparatus of an embodiment of the disclosure.

FIG. 6A to FIG. 6C show a repair process of a display apparatus of an embodiment of the disclosure.

FIG. 7A to FIG. 7C show a repair process of a display apparatus of an embodiment of the disclosure.

FIG. 8A to FIG. 8C show a repair process of a display apparatus of an embodiment of the disclosure.

### DESCRIPTION OF THE EMBODIMENTS

Reference will now be made in detail to exemplary embodiments of the disclosure, examples of which are illustrated in the accompanying drawings. Wherever possible, the same reference numerals are used in the drawings and the description to refer to the same or similar parts.

It should be understood that when an element such as a layer, film, region, or substrate is referred to as being “on”, or “connected to” another element, it may be directly on or connected to said another element, or intermediate elements may also be present. In contrast, when an element is referred to as being “directly on” or “directly connected to” another element, no intermediate elements are present. As used herein, the term “connection” may refer to physical connection and/or electrical connection. Furthermore, “electrical connection” or “coupling” may encompass the presence of other elements between two elements.

Unless otherwise defined, all terms (including technical and scientific terms) used herein have the same meaning as commonly understood by people of ordinary skill in the art. It will be further understood that terms, such as those defined in commonly used dictionaries, should be interpreted as having a meaning that is consistent with their meaning in the context of the relevant art and the disclosure and will not be interpreted in an idealized or overly formal sense unless explicitly so defined herein.

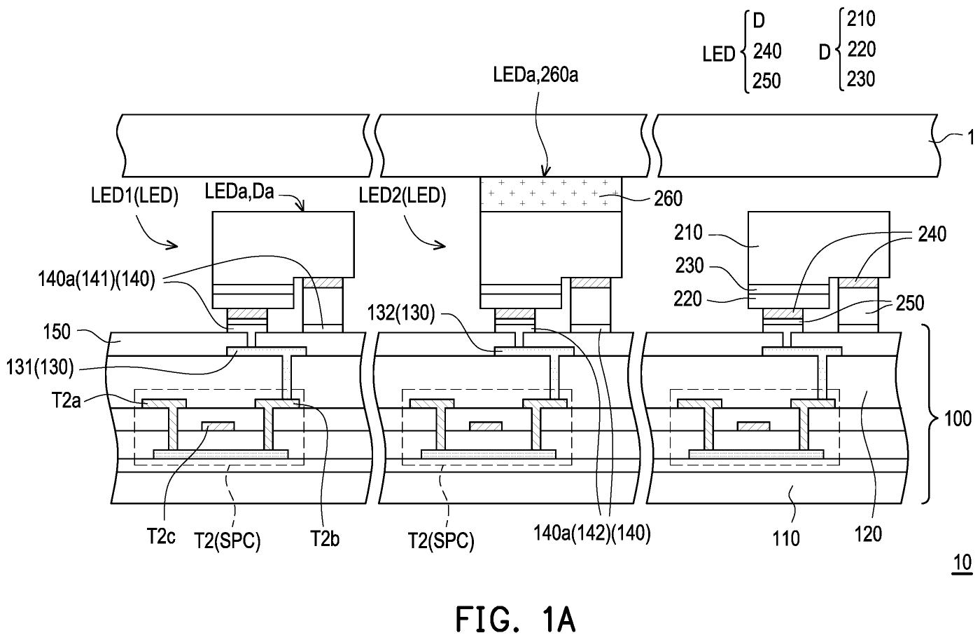

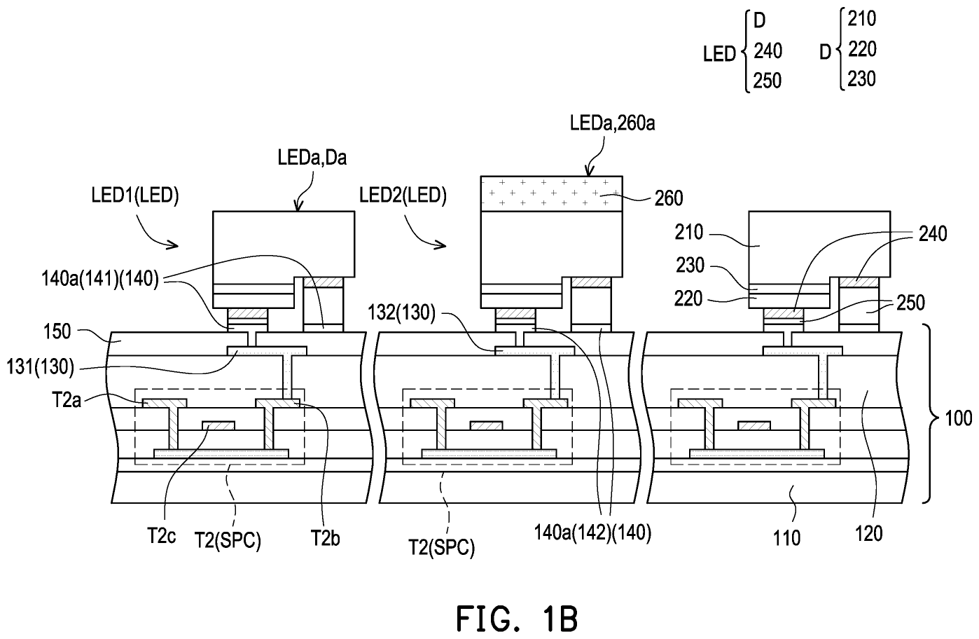

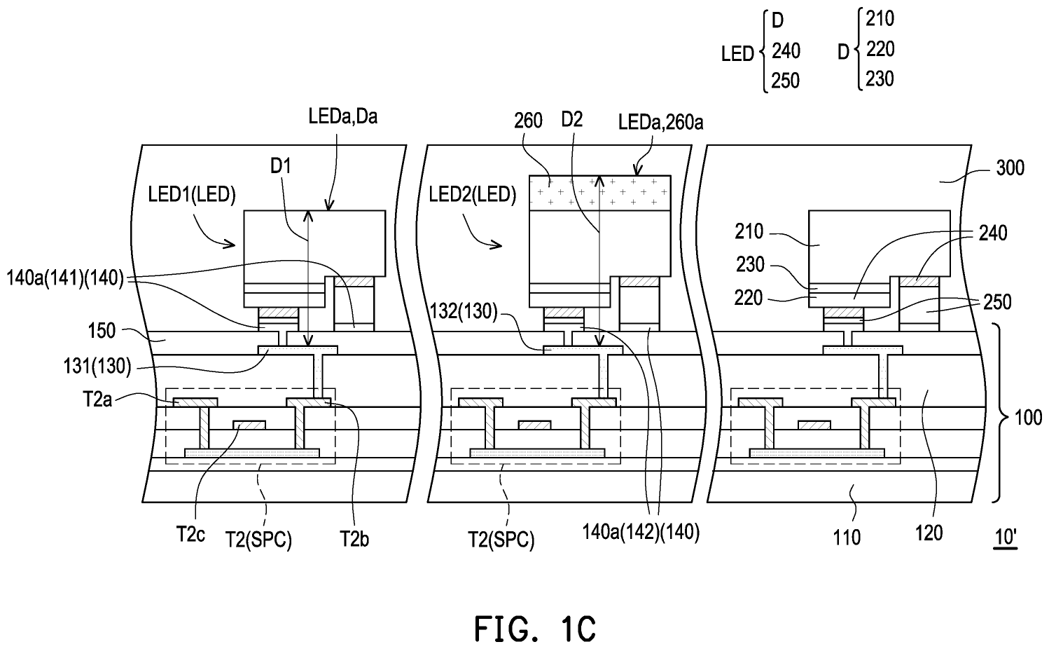

FIG. 1A to FIG. 1C show a repair process of a display apparatus of an embodiment of the disclosure.

With reference to FIG. 1A, a display apparatus 10 includes a driving backplane 100. The driving backplane 100 includes a substrate 110. For example, in this embodiment, the material of the substrate 110 may be glass, quartz, an organic polymer, or other applicable materials.

The display apparatus 10 further includes a plurality of pixel driving circuits SPC disposed on the substrate 110. For example, in this embodiment, each pixel driving circuit SPC may include a data line (not shown), a scan line (not shown), a power line (not shown), a common line (not shown), a first transistor (not shown), a second transistor T2, and a capacitor (not shown). The first end of the first transistor is electrically connected to the data line, the control end of the first transistor is electrically connected to the scan line, the second end of the first transistor is electrically connected to the control end T2c of the second transistor T2, the first end T2a of the second transistor T2 is electrically connected to the power line, and the capacitor is electrically connected to the second end of the first transistor and the first end T2a of the second transistor T2. Nonetheless, the disclosure is not limited thereto.

The driving backplane 100 further includes a conductive layer 130 having a plurality of conductive patterns 131 and 132. The conductive patterns 131 and 132 are respectively electrically connected to the pixel driving circuits SPC. For example, in this embodiment, each of the conductive patterns 131 and 132 may be electrically connected to the second end T2b of the second transistor T2 corresponding to one pixel driving circuit SPC, but the disclosure is not limited thereto.

In this embodiment, the conductive layer 130 is, for example, a transparent conductive layer, and includes metal oxide such as indium tin oxide, indium zinc oxide, aluminum tin oxide, aluminum zinc oxide, indium germanium zinc oxide, other suitable oxides, or a stacked layer of at least two of the above, but the disclosure is not limited thereto.

The driving backplane 100 further includes a pad layer 140 having a plurality of pad sets 141 and 142. The pad sets 141 and 142 are respectively electrically connected to the pixel driving circuits SPC. Each of the pad sets 141 and 142 includes a plurality of pads 140a. One pad 140a of each of the pad sets 141 and 142 is electrically connected to a corresponding one of the conductive patterns 131 and 132, and another one pad 140a of each of the pad sets 141 and 142 is electrically connected to the common line (not shown) of a corresponding pixel driving circuit SPC.

In this embodiment, the conductive layer 130 may be disposed on the pixel driving circuits SPC, and the driving backplane 100 may further include a dielectric layer 120 disposed between the conductive layer 130 and the pixel driving circuits SPC. In this embodiment, the pad layer 140 is disposed on the conductive layer 130, and the driving backplane 100 may further include another dielectric layer 150 disposed between the pad layer 140 and the conductive layer 130. In this embodiment, the materials of the dielectric layers 120 and 150 may be inorganic materials (e.g., silicon oxide, silicon nitride, silicon oxynitride, or a stacked layer of at least two of the above materials), organic materials, or a combination thereof.

The display apparatus 10 further includes a plurality of light-emitting elements LED. Each light-emitting element LED has a top surface LEDa facing away from the substrate 110. In this embodiment, each light-emitting element LED includes a die D, a plurality of electrodes 240, and a plurality of conductive bumps 250. The die D includes a first-type semiconductor layer 210, a second-type semiconductor layer 220, and an active layer 230 disposed between the first-type semiconductor layer 210 and the second-type semiconductor layer 220. The electrodes 240 are respectively electrically connected to the first-type semiconductor layer 210 and the second-type semiconductor layer 220, and the conductive bumps 250 are respectively electrically connected to the electrodes 240. The conductive bumps 250 of each light-emitting element LED are respectively electrically connected to the pads 140a of the corresponding ones of the pad sets 141 or 142.

The light-emitting elements LED are respectively electrically connected to the conductive patterns 131 and 132. To be specific, in this embodiment, the light-emitting elements LED are respectively electrically connected to the pad sets 141 and 142, and the pad sets 141 and 142 are respectively electrically connected to the conductive patterns 131 and 132. In this embodiment, the light-emitting elements LED may include micro-LEDs (μLEDs), but the disclosure is not limited thereto.

With reference to FIG. 1A and FIG. 1B, in this embodiment, detection may be performed on the display apparatus 10 to detect whether the light-emitting elements LED that have been transferred to the driving backplane 100 are normal. A normal light-emitting element LED (i.e., a first light-emitting element LED1) may be retained on the driving backplane 100, and an abnormal light-emitting element (not shown) may be removed. After that, a light-emitting element LED for repair (i.e., a second light-emitting element LED2) is transferred to and electrically connected to the driving backplane 100.

In this embodiment, compared to the normal light-emitting element LED (i.e., the first light-emitting element LED1) that is retained on the driving backplane 100, the light-emitting element LED for repair (i.e., the second light-emitting element LED2) further includes a color conversion pattern 260. The color conversion pattern 260 of the second light-emitting element LED2 is disposed on the die D of the second light-emitting element LED2.

When the second light-emitting element LED2 for repair is transferred to the driving backplane 100 by utilizing a transfer element 1, due to the color conversion pattern 260 of the second light-emitting element LED2 has, when pressed down to connect the second light-emitting element LED2 with the driving backplane 100, the transfer element 1 is not likely to damage the first light-emitting element LED1 that is normal and retained on the driving backplane 100.

With reference to FIG. 1B and FIG. 1C, after the repair above is completed, an encapsulation layer 300 may be formed on the driving backplane 100 to cover the first light-emitting element LED1 and the second light-emitting element LED2, and complete a repaired display apparatus 10′. The light-emitting elements LED of the display apparatus 10′ include the first light-emitting element LED1 and the second light-emitting element LED2. The conductive patterns 131 and 132 of the driving backplane 100 of the display apparatus 10′ include a first conductive pattern 131 and a second conductive pattern 132. The first light-emitting element LED1 and the second light-emitting element LED2 are respectively electrically connected to the first conductive pattern 131 and the second conductive pattern 132. A first distance D1 is between the top surface LEDa of the first light-emitting element LED1 and the first conductive pattern 131. A second distance D2 is between the top surface LEDa of the second light-emitting element LED2 and the second conductive pattern 132. The second distance D2 is greater than the first distance D1.

In this embodiment, the die D of the first light-emitting element LED1 has the top surface LEDa of the first light-emitting element LED1. The first distance D1 is between a top surface Da of the die D of the first light-emitting element LED1 and the first conductive pattern 131. The second light-emitting element LED2 includes the die D and the color conversion pattern 260. The color conversion pattern 260 of the second light-emitting element LED2 is disposed on the die D of the second light-emitting element LED2. The color conversion pattern 260 of the second light-emitting element LED2 has the top surface LEDa of the second light-emitting element LED2. Furthermore, the second distance D2 is between a top surface 260a of the color conversion pattern 260 of the second light-emitting element LED2 and the second conductive pattern 132. In other words, in this embodiment, the distance (i.e., the second distance D2) between the top surface 260a of the color conversion pattern 260 of the second light-emitting element LED2 and the second conductive pattern 132 is greater than the distance (i.e., the first distance DO between the top surface Da of the die D of the first light-emitting element LED1 and the first conductive pattern 131. The top surface LEDa of the first light-emitting element LED1 and the top surface 260a of the color conversion pattern 260 of the second light-emitting element LED2 are in direct contact with the encapsulation layer 300.

Note that, the reference numerals and part of the content of the embodiments above remain to be used in the embodiments below, where the same reference numerals are used to refer to the same or similar elements, and the description of the same technical content is omitted. Reference may be made to the embodiments above for the description of the omitted part, which will not be repeated in the embodiments below.

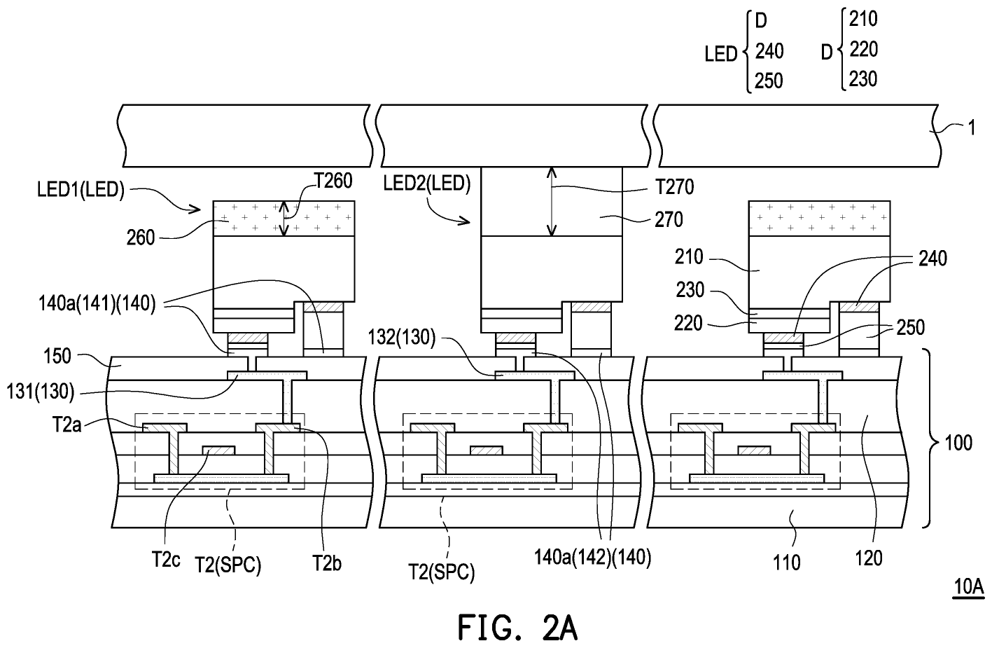

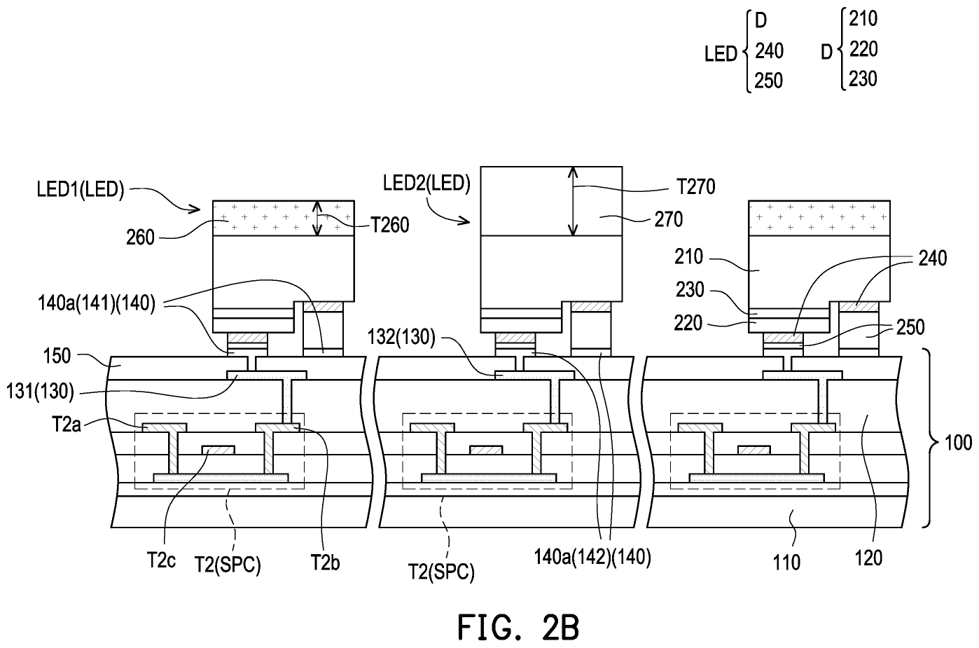

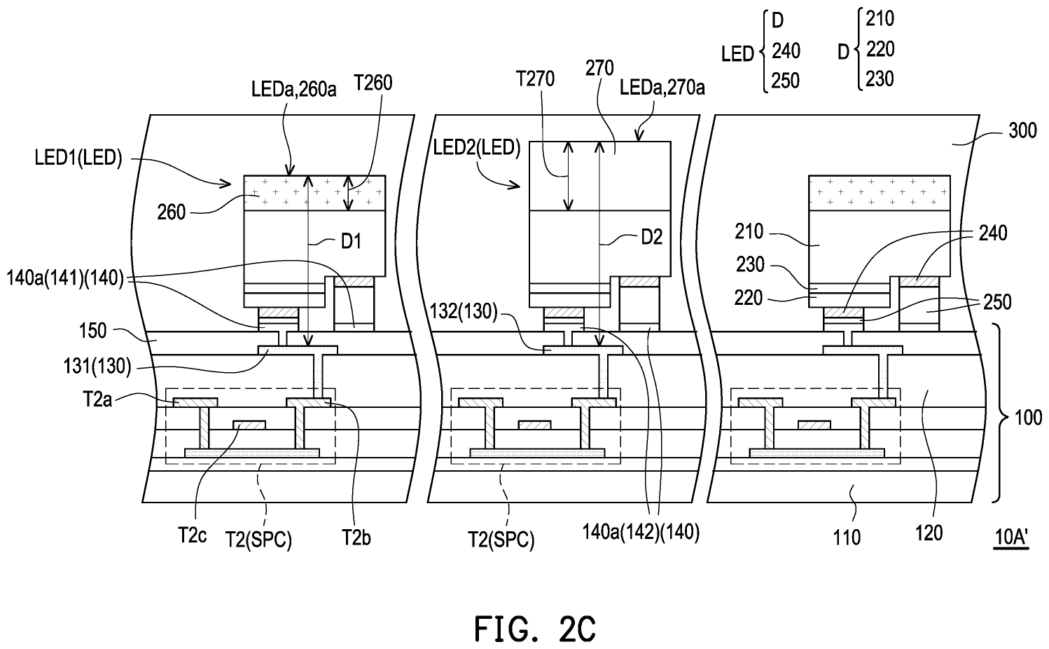

FIG. 2A to FIG. 2C show a repair process of a display apparatus of an embodiment of the disclosure.

Display apparatuses 10A and 10A′ of FIG. 2A to FIG. 2C are similar to the display apparatuses 10 and 10′ of FIG. 1A to FIG. 1C, and their difference lies in: the light-emitting elements LED of FIG. 2A to FIG. 2C are different from the light-emitting elements LED of FIG. 1A to FIG. 1C.

With reference to FIG. 2A, specifically, in this embodiment, the first light-emitting element LED1 that is normal retained on the driving backplane 100 includes the die D and the color conversion pattern 260, and the color conversion pattern 260 of the first light-emitting element LED1 is disposed on the die D of the first light-emitting element LED1; the second light-emitting element LED2 for repair includes the die D and a light transmitting pattern 270, and the light transmitting pattern 270 of the second light-emitting element LED2 is disposed on the die D of the second light-emitting element LED2.

A thickness T270 of the light transmitting pattern 270 of the second light-emitting element LED2 is greater than a thickness T260 of the color conversion pattern 260 of the first light-emitting element LED1. With reference to FIG. 2A and FIG. 2B, accordingly, when the second light-emitting element LED2 for repair is transferred to the driving backplane 100 by utilizing the transfer element 1, due to the greater thickness of the light transmitting pattern 270 of the second light-emitting element LED2, when pressed down to connect the second light-emitting element LED2 with the driving backplane 100, the transfer element 1 is not likely to damage the first light-emitting element LED1 that is normal and retained on the driving backplane 100.

With reference to FIG. 2C, the light-emitting elements LED of the repaired display apparatus 10A′ include the first light-emitting element LED1 and the second light-emitting element LED2. The conductive patterns 131 and 132 of the driving backplane 100 of the display apparatus 10A′ include the first conductive pattern 131 and the second conductive pattern 132. The first light-emitting element LED1 and the second light-emitting element LED2 are respectively electrically connected to the first conductive pattern 131 and the second conductive pattern 132. A first distance D1 is between the top surface LEDa of the first light-emitting element LED1 and the first conductive pattern 131. A second distance D2 is between the top surface LEDa of the second light-emitting element LED2 and the second conductive pattern 132. The second distance D2 is greater than the first distance D1.

In this embodiment, the light transmitting pattern 270 of the second light-emitting element LED2 has the top surface LEDa of the second light-emitting element LED2. The color conversion pattern 260 of the first light-emitting element LED1 has the top surface LEDa of the first light-emitting element LED1. The first distance D1 is between the top surface 260a of the color conversion pattern 260 of the first light-emitting element LED1 and the first conductive pattern 131. Furthermore, the second distance D2 is between a top surface 270a of the light transmitting pattern 270 of the second light-emitting element LED2 and the second conductive pattern 132. In other words, in this embodiment, the distance (i.e., the second distance D2) between the top surface 270a of the light transmitting pattern 270 of the second light-emitting element LED2 and the second conductive pattern 132 is greater than the distance (i.e., the first distance DO between the top surface 260a of the color conversion pattern 260 of the first light-emitting element LED1 and the first conductive pattern 131. The top surface 260a of the color conversion pattern 260 of the first light-emitting element LED1 and the top surface 270a of the light transmitting pattern 270 of the second light-emitting element LED2 are in direct contact with the encapsulation layer 300.

For example, in this embodiment, the die D of the first light-emitting element LED1 and the die D of the second light-emitting element LED2 are both configured to emit a same first color light (e.g., blue light). The color conversion pattern 260 of the first light-emitting element LED1 is configured to convert the first color light (e.g., blue light) into a second color light (e.g., red light or green light). The light transmitting pattern 270 of the second light-emitting element LED2 allow the first color light (e.g., blue light) to pass without converting the color of the first color light. Nonetheless, the disclosure is not limited thereto.

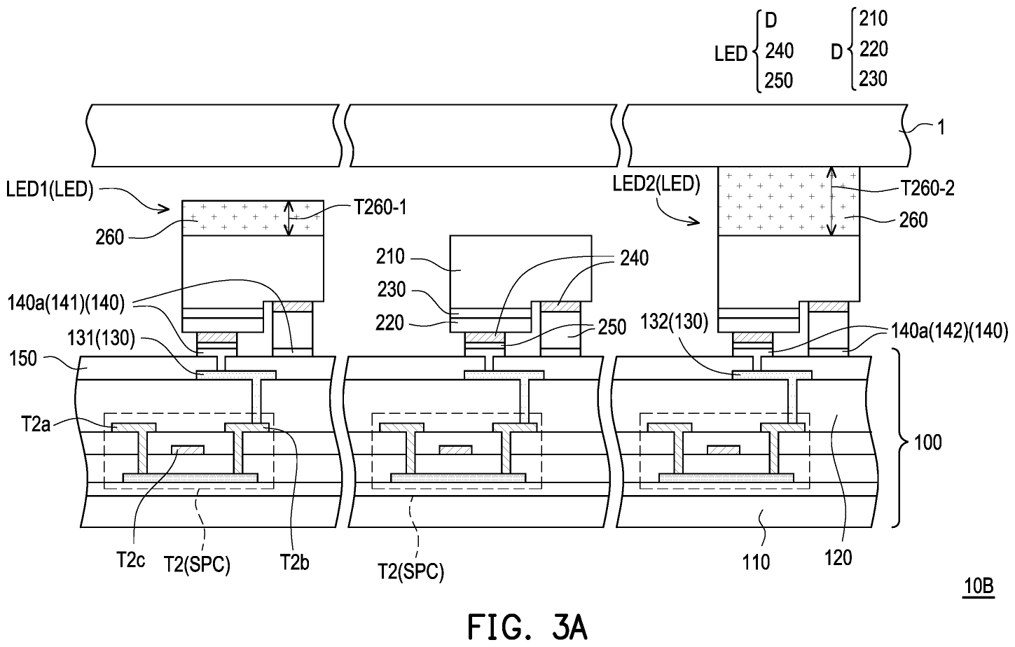

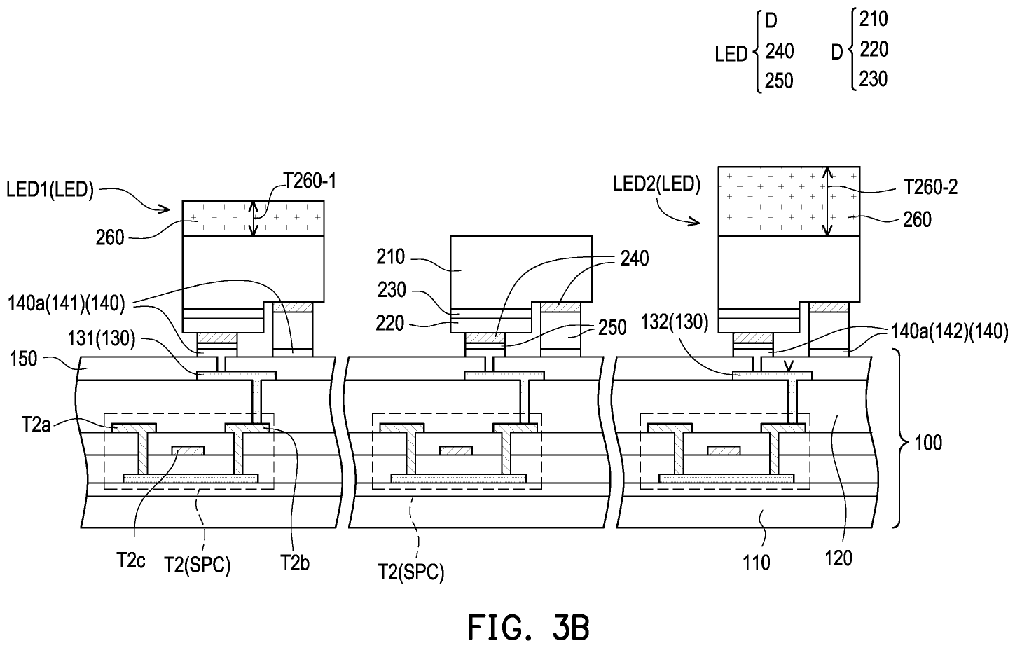

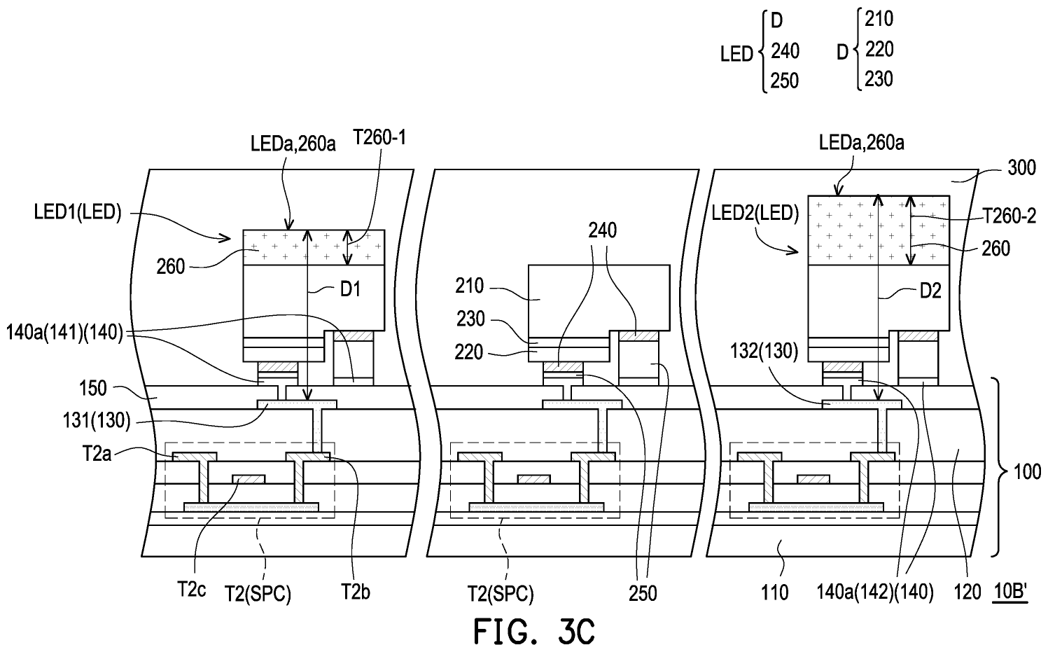

FIG. 3A to FIG. 3C show a repair process of a display apparatus of an embodiment of the disclosure.

Display apparatuses 10B and 10B′ of FIG. 3A to FIG. 3C are similar to the display apparatuses 10 and 10′ of FIG. 1A to FIG. 1C, and their difference lies in: the light-emitting elements LED of FIG. 3A to FIG. 3C are different from the light-emitting elements LED of FIG. 1A to FIG. 1C.

With reference to FIG. 3A, specifically, in this embodiment, the first light-emitting element LED1 that is normal and retained on the driving backplane 100 includes the die D and the color conversion pattern 260, and the color conversion pattern 260 of the first light-emitting element LED1 is disposed on the die D of the first light-emitting element LED1; the second light-emitting element LED2 for repair further includes the die D and the color conversion pattern 260, and the color conversion pattern 260 of the second light-emitting element LED2 is disposed on the die D of the second light-emitting element LED2.

A thickness T260-2 of the color conversion pattern 260 of the second light-emitting element LED2 for repair is greater than a thickness T260-1 of the color conversion pattern 260 of the first light-emitting element LED1. With reference to FIG. 3A and FIG. 3B, accordingly, when the second light-emitting element LED2 for repair is transferred to the driving backplane 100 by utilizing the transfer element 1, due to the greater thickness of the color conversion pattern 260 of the second light-emitting element LED2, when pressed down to connect the second light-emitting element LED2 with the driving backplane 100, the transfer element 1 is not likely to damage the first light-emitting element LED1 that is normal and retained on the driving backplane 100.

With reference to FIG. 3C, the light-emitting elements LED of the repaired display apparatus 10B′ include the first light-emitting element LED1 and the second light-emitting element LED2. The conductive patterns 131 and 132 of the driving backplane 100 of the display apparatus 10B′ include the first conductive pattern 131 and the second conductive pattern 132. The first light-emitting element LED1 and the second light-emitting element LED2 are respectively electrically connected to the first conductive pattern 131 and the second conductive pattern 132. A first distance D1 is between the top surface LEDa of the first light-emitting element LED1 and the first conductive pattern 131. A second distance D2 is between the top surface LEDa of the second light-emitting element LED2 and the second conductive pattern 132. The second distance D2 is greater than the first distance D1.

In this embodiment, the color conversion pattern 260 of the second light-emitting element LED2 has the top surface LEDa of the second light-emitting element LED2. The color conversion pattern 260 of the first light-emitting element LED1 has the top surface LEDa of the first light-emitting element LED1. The first distance D1 is between the top surface 260a of the color conversion pattern 260 of the first light-emitting element LED1 and the first conductive pattern 131. Furthermore, the second distance D2 is between the top surface 260a of the color conversion pattern 260 of the second light-emitting element LED2 and the second conductive pattern 132. In other words, in this embodiment, the distance (i.e., the second distance D2) between the top surface 260a of the color conversion pattern 260 of the second light-emitting element LED2 and the second conductive pattern 132 is greater than the distance (i.e., the first distance DO between the top surface 260a of the color conversion pattern 260 of the die D of the first light-emitting element LED1 and the first conductive pattern 131. The top surface 260a of the color conversion pattern 260 of the first light-emitting element LED1 and the top surface 260a of the color conversion pattern 260 of the second light-emitting element LED2 are in direct contact with the encapsulation layer 300.

For example, in this embodiment, the die D of the first light-emitting element LED1 and the die D of the second light-emitting element LED2 are both configured to emit a same first color light (e.g., blue light). The color conversion pattern 260 of the first light-emitting element LED1 is configured to convert the first color light (e.g., blue light) into a second color light (e.g., red light). The color conversion pattern 260 of the second light-emitting element LED2 is configured to convert the first color light (e.g., blue light) into a third color light (e.g., green light).

Nonetheless, the disclosure is not limited thereto.

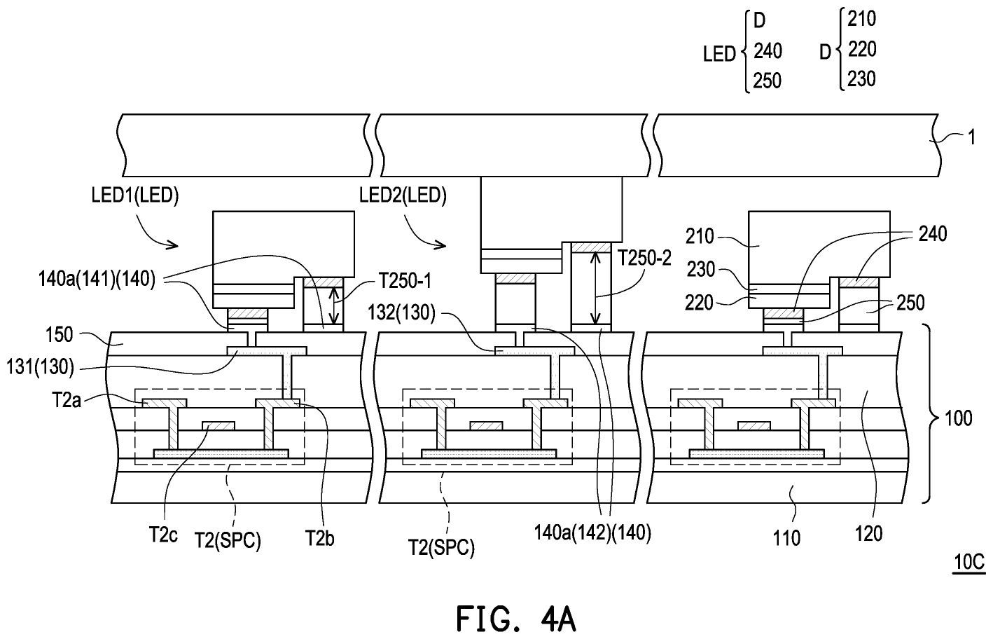

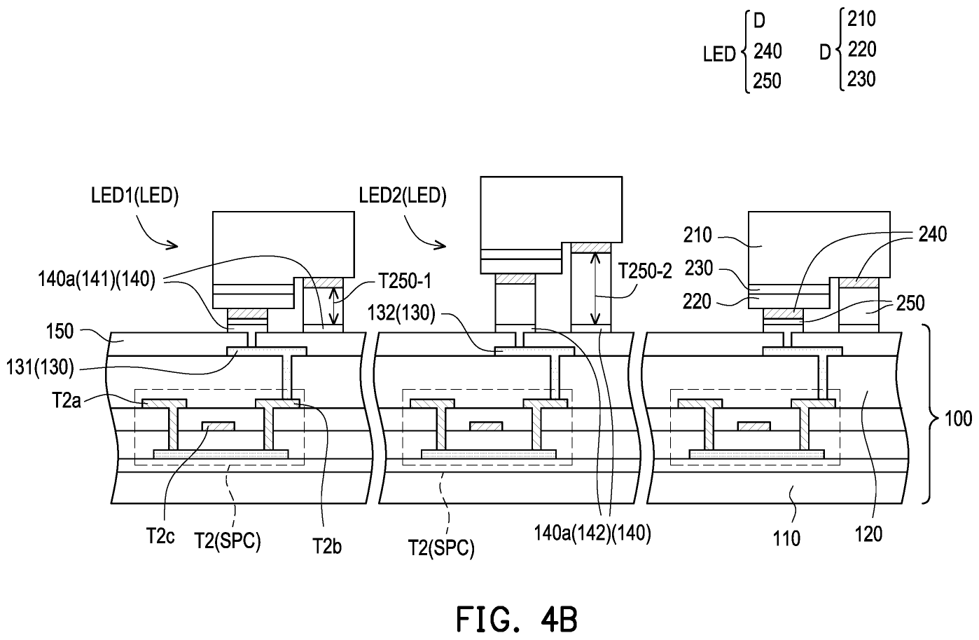

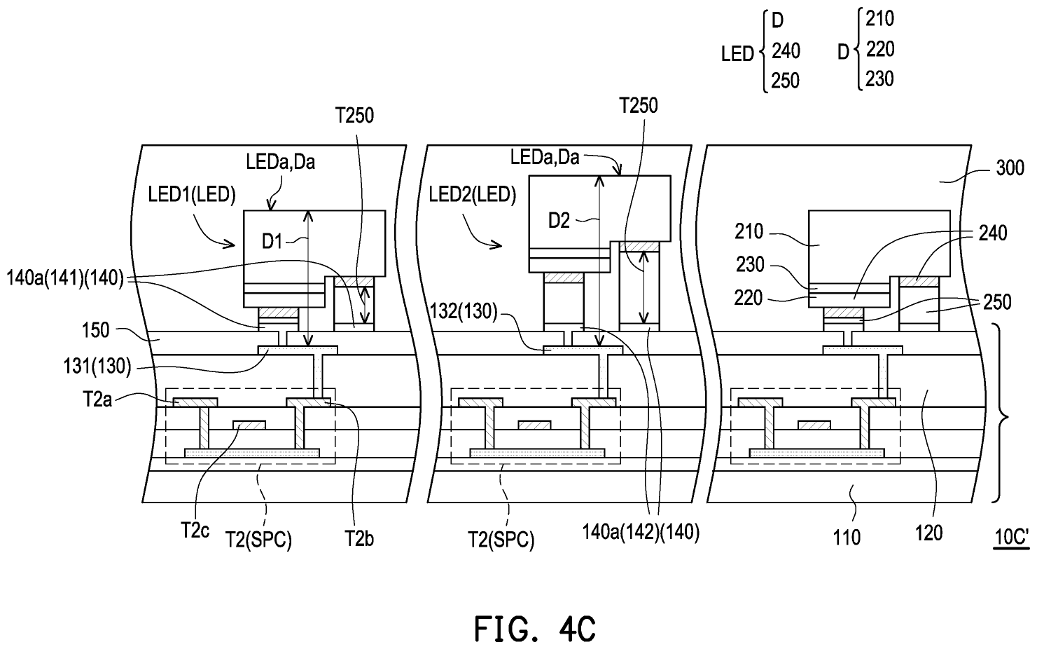

FIG. 4A to FIG. 4C show a repair process of a display apparatus of an embodiment of the disclosure.

Display apparatuses 10C and 10C′ of FIG. 4A to FIG. 4C are similar to the display apparatuses 10 and 10′ of FIG. 1A to FIG. 1C, and their difference lies in: the light-emitting elements LED of FIG. 4A to FIG. 4C are different from the light-emitting elements LED of FIG. 1A to FIG. 1C.

With reference to FIG. 4A, specifically, in this embodiment, a thickness T250-2 of at least one of the conductive bumps 250 of the second light-emitting element LED2 is greater than a thickness T250-1 of at least one of the conductive bumps 250 of the first light-emitting element LED1. With reference to FIG. 4A and FIG. 4B, accordingly, when the second light-emitting element LED2 for repair is transferred to the driving backplane 100 by utilizing the transfer element 1, due to the greater thickness of the conductive bump 250 of the second light-emitting element LED2, when pressed down to connect the second light-emitting element LED2 with the driving backplane 100, the transfer element 1 is not likely to damage the first light-emitting element LED1 that is normal and retained on the driving backplane 100.

With reference to FIG. 4C, the light-emitting elements LED of the repaired display apparatus 10C′ include the first light-emitting element LED1 and the second light-emitting element LED2. The conductive patterns 131 and 132 of the driving backplane 100 of the display apparatus 10C′ include the first conductive pattern 131 and the second conductive pattern 132. The first light-emitting element LED1 and the second light-emitting element LED2 are respectively electrically connected to the first conductive pattern 131 and the second conductive pattern 132. A first distance D1 is between the top surface LEDa of the first light-emitting element LED1 and the first conductive pattern 131. A second distance D2 is between the top surface LEDa of the second light-emitting element LED2 and the second conductive pattern 132. The second distance D2 is greater than the first distance D1.

In this embodiment, the die D of the second light-emitting element LED2 has the top surface LEDa of the second light-emitting element LED2. The die D of the first light-emitting element LED1 has the top surface LEDa of the first light-emitting element LED1. The first distance D1 is between the top surface Da of the die D of the first light-emitting element LED1 and the first conductive pattern 131. Furthermore, the second distance D2 is between the top surface Da of the die D of the second light-emitting element LED2 and the second conductive pattern 132. In other words, in this embodiment, the distance (i.e., the second distance D2) between the top surface Da of the die D of the second light-emitting element LED2 and the second conductive pattern 132 is greater than the distance (i.e., the first distance DO between the top surface Da of the die D of the first light-emitting element LED1 and the first conductive pattern 131. The top surface Da of the die D of the first light-emitting element LED1 and the top surface Da of the die D of the second light-emitting element LED2 are in direct contact with the encapsulation layer 300.

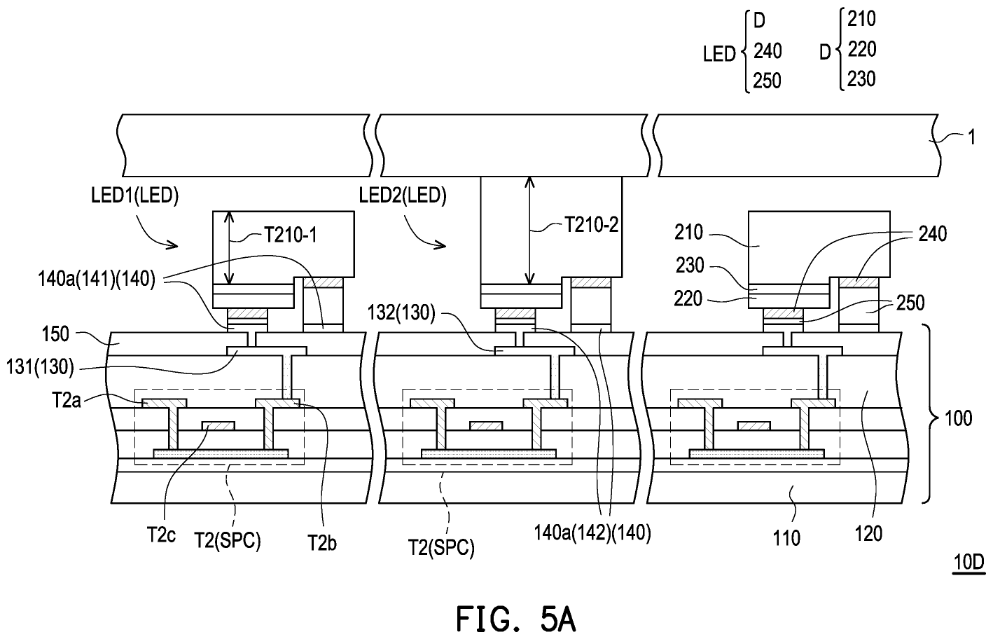

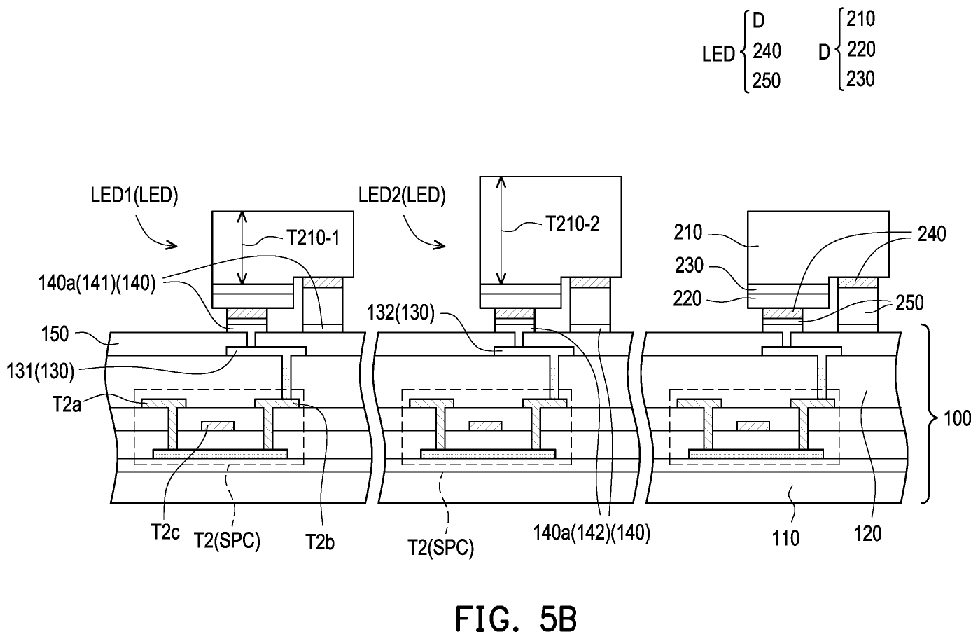

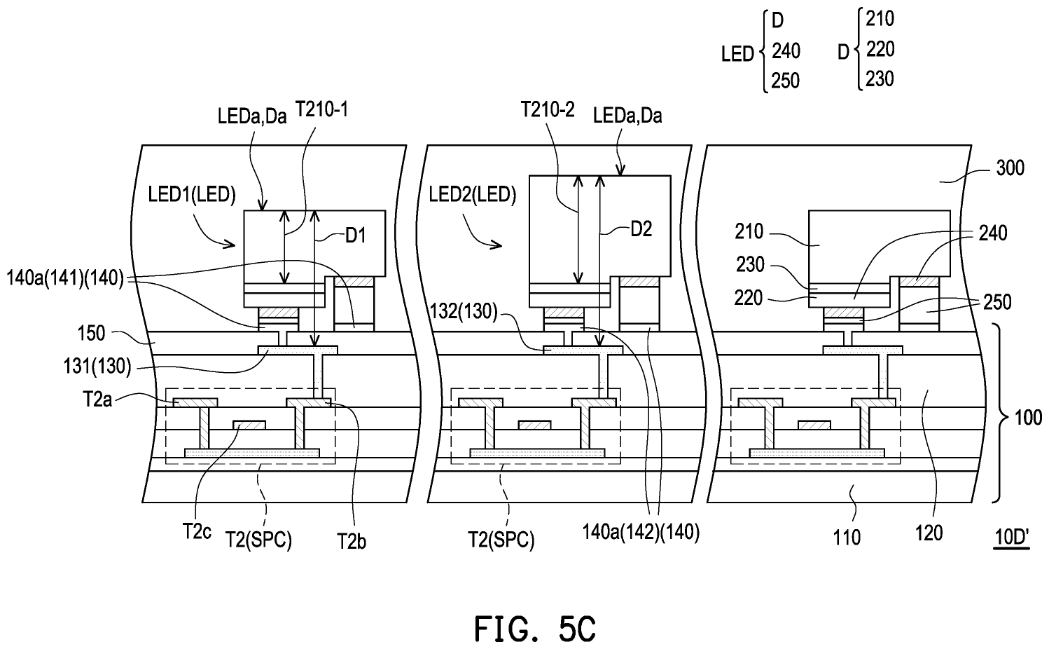

FIG. 5A to FIG. 5C show a repair process of a display apparatus of an embodiment of the disclosure.

Display apparatuses 10D and 10D′ of FIG. 5A to FIG. 5C are similar to the display apparatuses 10 and 10′ of FIG. 1A to FIG. 1C, and their difference lies in: the light-emitting elements LED of FIG. 5A to FIG. 5C are different from the light-emitting elements LED of FIG. 1A to FIG. 1C.

With reference to FIG. 5A, specifically, in this embodiment, a thickness T210-2 of the first-type semiconductor layer 210 of the second light-emitting element LED2 is greater than a thickness T210-1 of the first-type semiconductor layer 210 of the first light-emitting element LED1. With reference to FIG. 5A and FIG. 5B, accordingly, when the second light-emitting element LED2 for repair is transferred to the driving backplane 100 by utilizing the transfer element 1, due to the greater thickness of the first-type semiconductor layer 210 of the second light-emitting element LED2, when pressed down to connect the second light-emitting element LED2 with the driving backplane 100, the transfer element 1 is not likely to damage the first light-emitting element LED1 that is normal and retained on the driving backplane 100.

With reference to FIG. 5C, the light-emitting elements LED of the repaired display apparatus 10D′ include the first light-emitting element LED1 and the second light-emitting element LED2. The conductive patterns 131 and 132 of the driving backplane 100 of the display apparatus 10D′ include the first conductive pattern 131 and the second conductive pattern 132. The first light-emitting element LED1 and the second light-emitting element LED2 are respectively electrically connected to the first conductive pattern 131 and the second conductive pattern 132. A first distance D1 is between the top surface LEDa of the first light-emitting element LED1 and the first conductive pattern 131. A second distance D2 is between the top surface LEDa of the second light-emitting element LED2 and the second conductive pattern 132. The second distance D2 is greater than the first distance D1.

In this embodiment, the die D of the second light-emitting element LED2 has the top surface LEDa of the second light-emitting element LED2. The die D of the first light-emitting element LED1 has the top surface LEDa of the first light-emitting element LED1. The first distance D1 is between the top surface Da of the die D of the first light-emitting element LED1 and the first conductive pattern 131. Furthermore, the second distance D2 is between the top surface Da of the die D of the second light-emitting element LED2 and the second conductive pattern 132. In other words, in this embodiment, the distance (i.e., the second distance D2) between the top surface Da of the die D of the second light-emitting element LED2 and the second conductive pattern 132 is greater than the distance (i.e., the first distance DO between the top surface Da of the die D of the first light-emitting element LED1 and the first conductive pattern 131. The top surface Da of the die D of the first light-emitting element LED1 and the top surface Da of the die D of the second light-emitting element LED2 are in direct contact with the encapsulation layer 300.

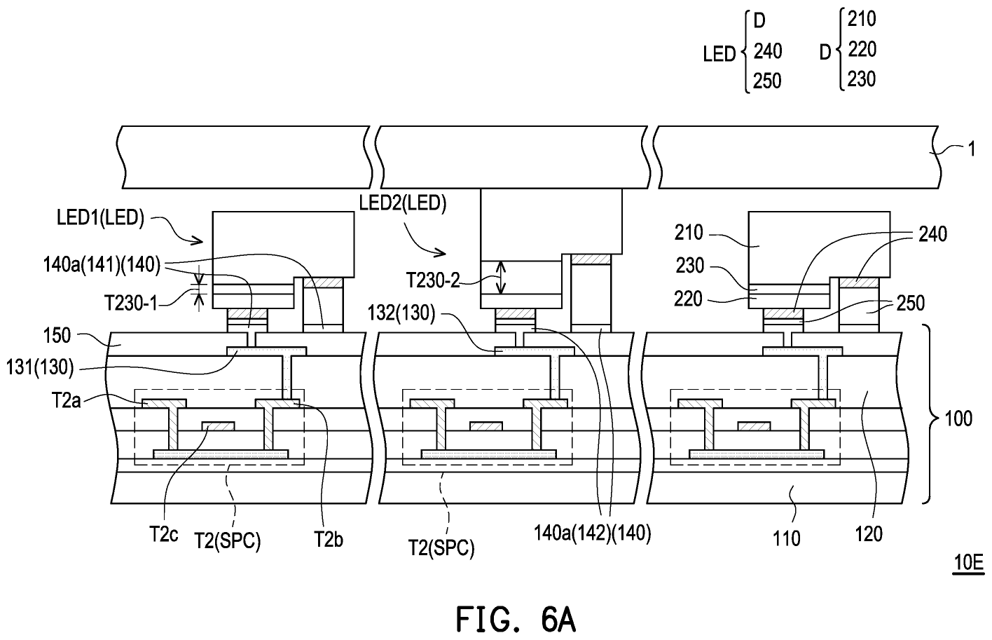

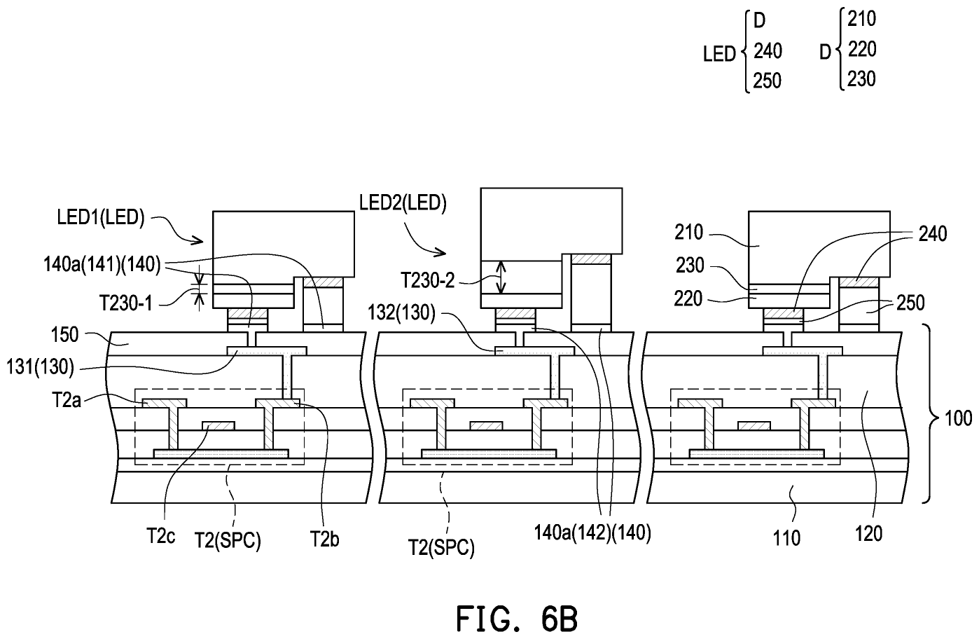

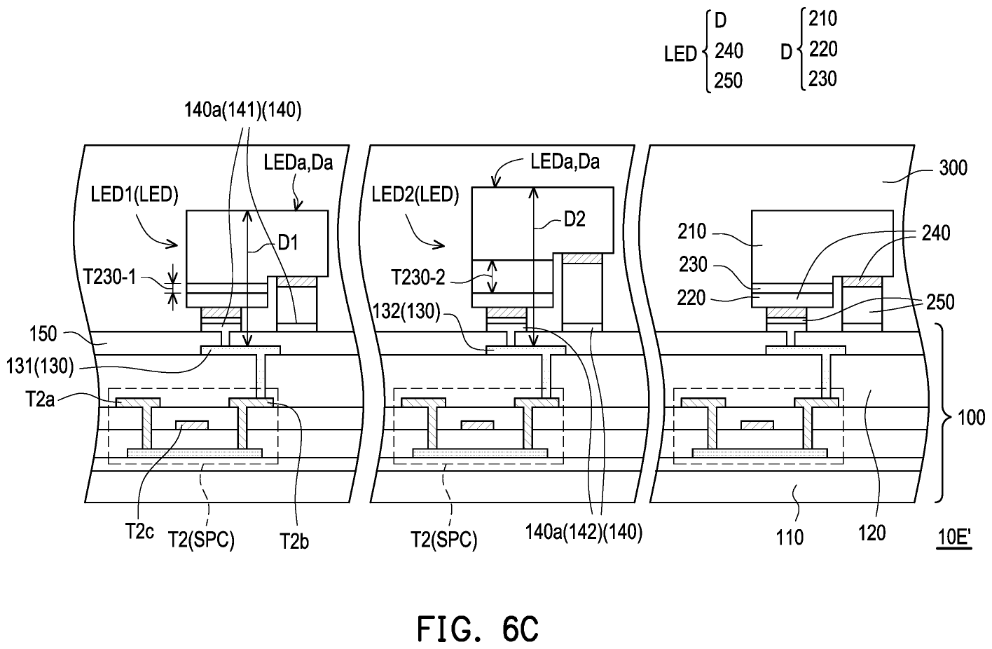

FIG. 6A to FIG. 6C show a repair process of a display apparatus of an embodiment of the disclosure.

Display apparatuses 10E and 10E′ of FIG. 6A to FIG. 6C are similar to the display apparatuses 10 and 10′ of FIG. 1A to FIG. 1C, and their difference lies in: the light-emitting elements LED of FIG. 6A to FIG. 6C are different from the light-emitting elements LED of FIG. 1A to FIG. 1C.

With reference to FIG. 6A, specifically, in this embodiment, a thickness T230-2 of the active layer 230 of the second light-emitting element LED2 for repair is greater than a thickness T230-1 of the active layer 230 of the first light-emitting element LED1. With reference to FIG. 6A and FIG. 6B, accordingly, when the second light-emitting element LED2 for repair is transferred to the driving backplane 100 by utilizing the transfer element 1, due to the greater thickness of the active layer 230 of the second light-emitting element LED2, when pressed down to connect the second light-emitting element LED2 with the driving backplane 100, the transfer element 1 is not likely to damage the first light-emitting element LED1 that is normal and retained on the driving backplane 100.

With reference to FIG. 6C, the light-emitting elements LED of the repaired display apparatus 10E′ include the first light-emitting element LED1 and the second light-emitting element LED2. The conductive patterns 131 and 132 of the driving backplane 100 of the display apparatus 10E′ include the first conductive pattern 131 and the second conductive pattern 132. The first light-emitting element LED1 and the second light-emitting element LED2 are respectively electrically connected to the first conductive pattern 131 and the second conductive pattern 132. A first distance D1 is between the top surface LEDa of the first light-emitting element LED1 and the first conductive pattern 131. A second distance D2 is between the top surface LEDa of the second light-emitting element LED2 and the second conductive pattern 132. The second distance D2 is greater than the first distance D1.

In this embodiment, the die D of the second light-emitting element LED2 has the top surface LEDa of the second light-emitting element LED2. The die D of the first light-emitting element LED1 has the top surface LEDa of the first light-emitting element LED1. The first distance D1 is between the top surface Da of the die D of the first light-emitting element LED1 and the first conductive pattern 131. Furthermore, the second distance D2 is between the top surface Da of the die D of the second light-emitting element LED2 and the second conductive pattern 132. In other words, in this embodiment, the distance (i.e., the second distance D2) between the top surface Da of the die D of the second light-emitting element LED2 and the second conductive pattern 132 is greater than the distance (i.e., the first distance DO between the top surface Da of the die D of the first light-emitting element LED1 and the first conductive pattern 131. The top surface Da of the die D of the first light-emitting element LED1 and the top surface Da of the die D of the second light-emitting element LED2 are in direct contact with the encapsulation layer 300.

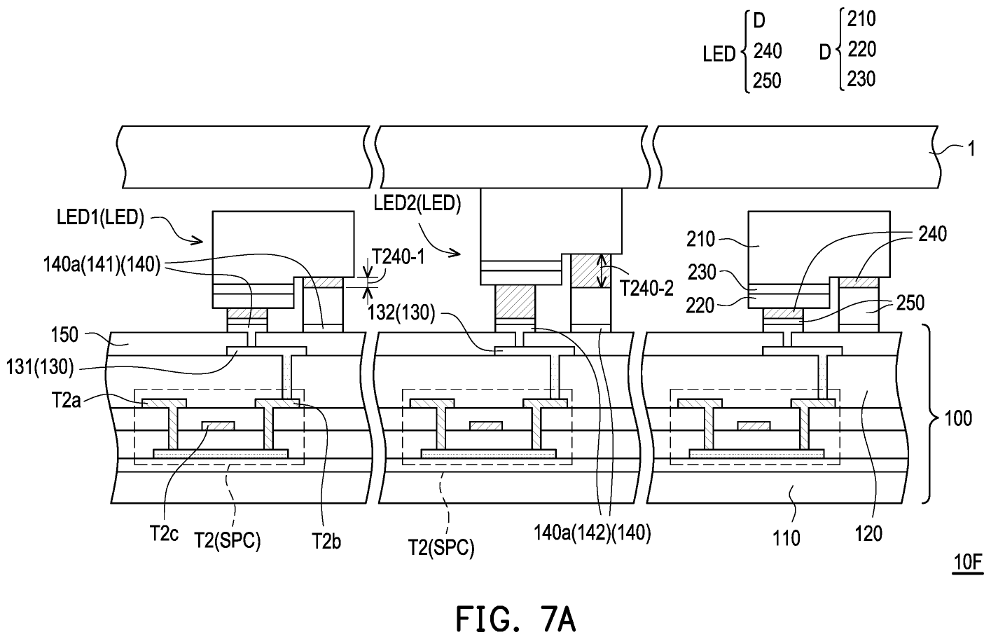

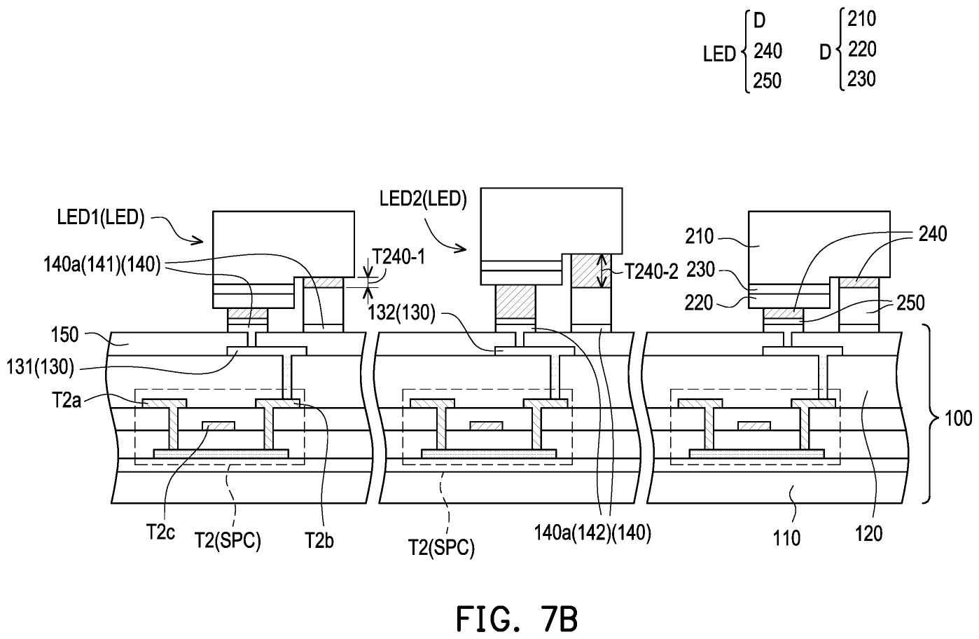

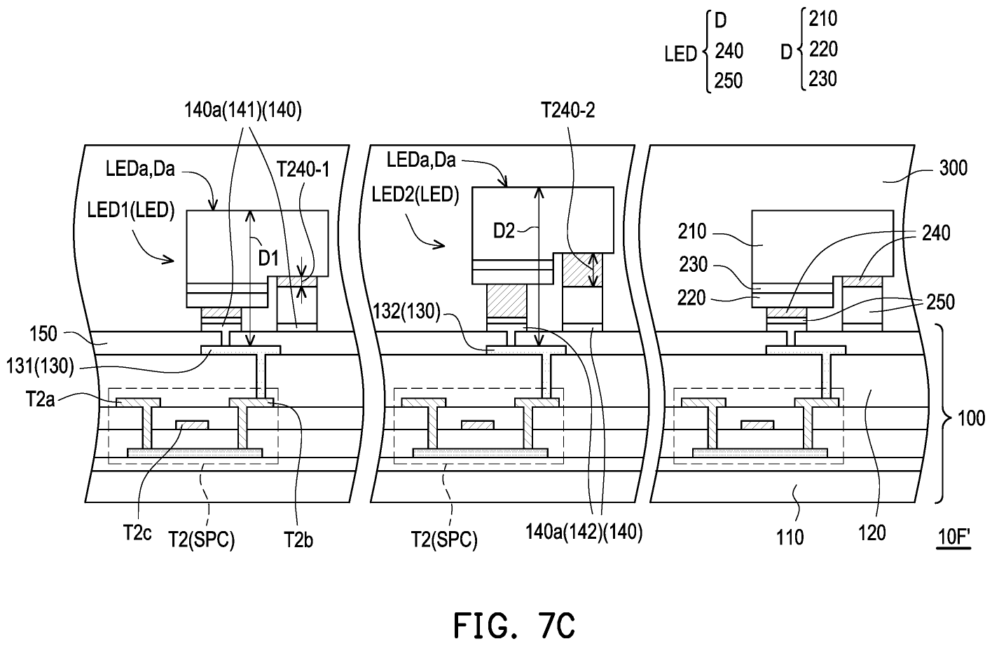

FIG. 7A to FIG. 7C show a repair process of a display apparatus of an embodiment of the disclosure.

Display apparatuses 10F and 10F′ of FIG. 7A to FIG. 7C are similar to the display apparatuses 10 and 10′ of FIG. 1A to FIG. 1C, and their difference lies in: the light-emitting elements LED of FIG. 7A to FIG. 7C are different from the light-emitting elements LED of FIG. 1A to FIG. 1C.

With reference to FIG. 7A, specifically, in this embodiment, a thickness T240-2 of at least one of the electrodes 240 of the second light-emitting element LED for repair is greater than a thickness T240-1 of at least one of the electrodes 240 of the first light-emitting element LED1. With reference to FIG. 7A and FIG. 7B, accordingly, when the second light-emitting element LED2 for repair is transferred to the driving backplane 100 by utilizing the transfer element 1, due to the greater thickness of the electrode 240 of the second light-emitting element LED2, when pressed down to connect the second light-emitting element LED2 with the driving backplane 100, the transfer element 1 is not likely to damage the first light-emitting element LED1 that is normal and retained on the driving backplane 100.

With reference to FIG. 7C, the light-emitting elements LED of the repaired display apparatus 10F′ include the first light-emitting element LED1 and the second light-emitting element LED2. The conductive patterns 131 and 132 of the driving backplane 100 of the display apparatus 10F′ include the first conductive pattern 131 and the second conductive pattern 132. The first light-emitting element LED1 and the second light-emitting element LED2 are respectively electrically connected to the first conductive pattern 131 and the second conductive pattern 132. A first distance D1 is between the top surface LEDa of the first light-emitting element LED1 and the first conductive pattern 131. A second distance D2 is between the top surface LEDa of the second light-emitting element LED2 and the second conductive pattern 132. The second distance D2 is greater than the first distance D1.

In this embodiment, the die D of the second light-emitting element LED2 has the top surface LEDa of the second light-emitting element LED2. The die D of the first light-emitting element LED1 has the top surface LEDa of the first light-emitting element LED1. The first distance D1 is between the top surface Da of the die D of the first light-emitting element LED1 and the first conductive pattern 131. Furthermore, the second distance D2 is between the top surface Da of the die D of the second light-emitting element LED2 and the second conductive pattern 132. In other words, in this embodiment, the distance (i.e., the second distance D2) between the top surface Da of the die D of the second light-emitting element LED2 and the second conductive pattern 132 is greater than the distance (i.e., the first distance DO between the top surface Da of the die D of the first light-emitting element LED1 and the first conductive pattern 131. The top surface Da of the die D of the first light-emitting element LED1 and the top surface Da of the die D of the second light-emitting element LED2 are in direct contact with the encapsulation layer 300.

In FIG. 1A to FIG. 1C, FIG. 2A to FIG. 2C, FIG. 3A to FIG. 3C, FIG. 4A to FIG. 4C, FIG. 5A to FIG. 5C, FIG. 6A to FIG. 6C, and FIG. 7A to FIG. 7C, the second light-emitting element LED2 may serve for on-site repair or off-site repair.

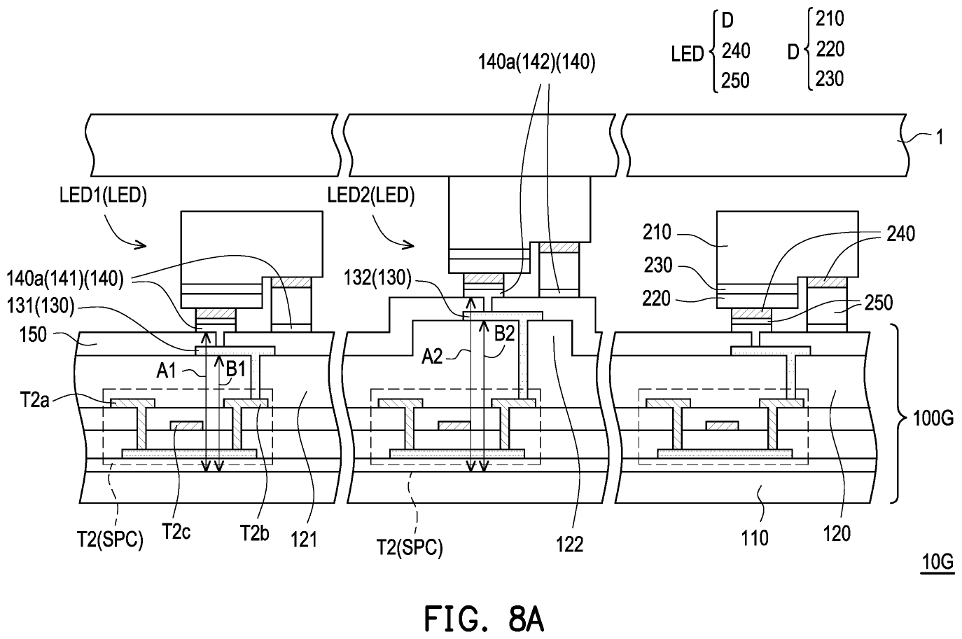

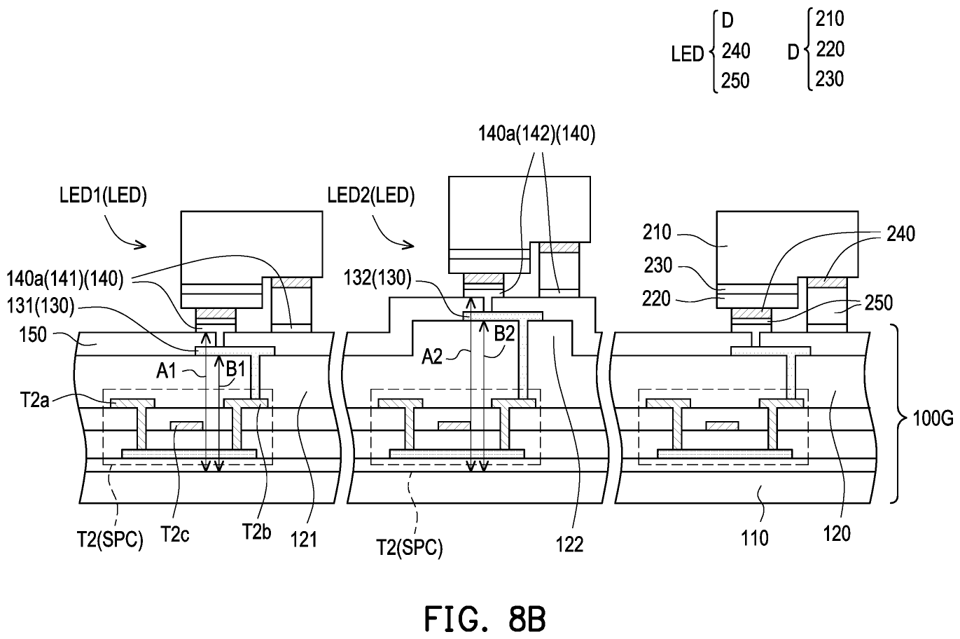

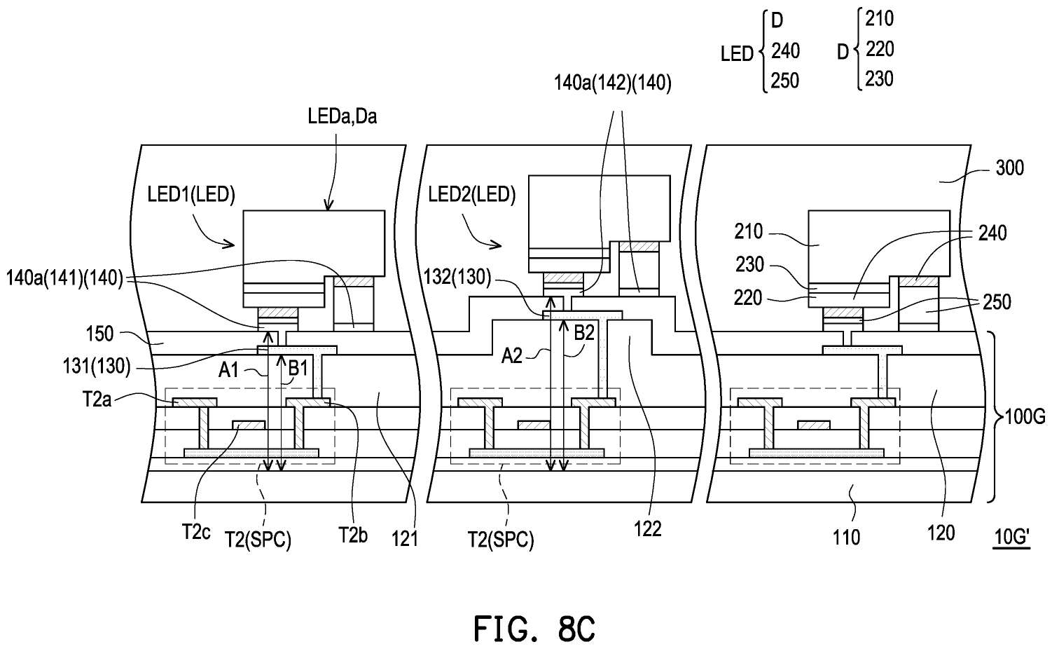

FIG. 8A to FIG. 8C show a repair process of a display apparatus of an embodiment of the disclosure.

A display apparatus 10G of FIG. 8A to FIG. 8C is similar to the display apparatus 10 of FIG. 1A to FIG. 1C, and their difference lies in: a driving backplane 100G of the embodiment of FIG. 8A to FIG. 8C is different from the driving backplane 100 of the embodiment of FIG. 1A to FIG. 1C.

With reference to FIG. 8A, specifically, in this embodiment, the dielectric layer 120 of the driving backplane 100G is disposed between the pad layer 140 and the substrate 110. In particular, the dielectric layer 120 includes a flat part 121 and a protrusive part 122 protruding from the flat part 121. In this embodiment, the region where the flat part 121 of the driving backplane 100G is located serves for disposing the first light-emitting element LED1 that is transferred to the driving backplane 100G for the first time, and the region where the protrusive part 122 of the driving backplane 100G is located serves for off-site repair.

With reference to FIG. 8A, detection may be performed on the display apparatus 10G to detect whether the light-emitting elements LED that have been transferred to the driving backplane 100G is normal. A normal light-emitting element LED (i.e., the first light-emitting element LED1) may be retained on the driving backplane 100G, and an abnormal light-emitting element (not shown) may be removed. After that, the light-emitting element LED for repair (i.e., the second light-emitting element LED2) is transferred to and electrically connected to the driving backplane 100G.

In this embodiment, the second light-emitting element LED2 for repair is transferred to the protrusive part 122 of the dielectric layer 120. Therefore, when pressed down to connect the second light-emitting element LED2 with the driving backplane 100, the transfer element 1 is not likely to damage the first light-emitting element LED1 that is normal and retained on the driving backplane 100.

With reference to FIG. 8B and FIG. 8C, after the repair above is completed, the encapsulation layer 300 may be formed on the driving backplane 100G to cover the first light-emitting element LED1 and the second light-emitting element LED2, and complete a repaired display apparatus 10G′. With reference to FIG. 8C, the second light-emitting element LED2 for repair of the display apparatus 10G′ overlaps the protrusive part 122 of the dielectric layer 120, and the first light-emitting element LED1 of the display apparatus 10G′ overlaps the flat part 121 of the dielectric layer 120. The light-emitting elements LED of the display apparatus 10G′ include the first light-emitting element LED1 and the second light-emitting element LED2. The pad sets 141 and 142 of the display apparatus 10G′ include a first pad set 141 and a second pad set 142. The first light-emitting element LED1 and the second light-emitting element LED2 are respectively electrically connected to the first pad set 141 and the second pad set 142. A distance A2 between the at least one pad 140a of the second pad set 142 and the substrate 110 is greater than a distance A1 between the at least one pad 140a of the first pad set 141 and the substrate 110.

In this embodiment, the dielectric layer 120 having the protrusive part 122 may be selectively located between the conductive layer 130 and the pixel driving circuits SPC. The second conductive pattern 132 may be located on the protrusive part 122 of the dielectric layer 120. The first conductive pattern 131 may be located on the flat part 121 of the dielectric layer 120. A distance B2 between the second conductive pattern 132 and the substrate 110 may be greater than a distance B1 between the first conductive pattern 131 and the substrate 110. Nonetheless, the disclosure is not limited thereto. In other embodiments, the protrusive part for disposing the second light-emitting element LED2 for off-site repair may also be formed by using other film layers (e.g., the dielectric layer 150).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus comprising:
a driving backplane comprising:
a substrate;
a plurality of pixel driving circuits disposed on the substrate; and
a conductive layer having a plurality of conductive patterns, wherein the conductive patterns are respectively electrically connected to the pixel driving circuits; and
a plurality of light-emitting elements respectively electrically connected to the conductive patterns, wherein each of the light-emitting elements has a top surface facing away from the substrate;
wherein the light-emitting elements comprise a first light-emitting element and a second light-emitting element, the conductive patterns comprise a first conductive pattern and a second conductive pattern, and the first light-emitting element and the second light-emitting element are respectively electrically connected to the first conductive pattern and the second conductive pattern,
wherein a first distance is between the top surface of the first light-emitting element and the first conductive pattern, a second distance is between the top surface of the second light-emitting element and the second conductive pattern, and the second distance is greater than the first distance.

2. The display apparatus according to claim 1, wherein the first light-emitting element comprises a die, the die of the first light-emitting element has the top surface of the first light-emitting element, and the first distance is between a top surface of the die of the first light-emitting element and the first conductive pattern; and
wherein the second light-emitting element comprises a die and a color conversion pattern, the color conversion pattern of the second light-emitting element is disposed on the die of the second light-emitting element, the color conversion pattern of the second light-emitting element has the top surface of the second light-emitting element, and the second distance is between a top surface of the color conversion pattern of the second light-emitting element and the second conductive pattern.

3. The display apparatus according to claim 1, wherein the first light-emitting element comprises a die and a color conversion pattern, the color conversion pattern of the first light-emitting element is disposed on the die of the first light-emitting element, the color conversion pattern of the first light-emitting element has the top surface of the first light-emitting element, and the first distance is between a top surface of the color conversion pattern of the first light-emitting element and the first conductive pattern;
wherein the second light-emitting element comprises a die and a color conversion pattern, the color conversion pattern of the second light-emitting element is disposed on the die of the second light-emitting element, the color conversion pattern of the second light-emitting element has the top surface of the second light-emitting element, and the second distance is between a top surface of the color conversion pattern of the second light-emitting element and the second conductive pattern; and
wherein a thickness of the color conversion pattern of the second light-emitting element is greater than a thickness of the color conversion pattern of the first light-emitting element.

4. The display apparatus according to claim 1, wherein the first light-emitting element comprises a die and a color conversion pattern, the color conversion pattern of the first light-emitting element is disposed on the die of the first light-emitting element, the color conversion pattern of the first light-emitting element has the top surface of the first light-emitting element, and the first distance is between a top surface of the color conversion pattern of the first light-emitting element and the first conductive pattern;
wherein the second light-emitting element comprises a die and a light transmitting pattern, the light transmitting pattern of the second light-emitting element is disposed on the die of the second light-emitting element, the light transmitting pattern of the second light-emitting element has the top surface of the second light-emitting element, and the second distance is between a top surface of the light transmitting pattern of the second light-emitting element and the second conductive pattern; and
wherein a thickness of the light transmitting pattern of the second light-emitting element is greater than a thickness of the color conversion pattern of the first light-emitting element.

5. The display apparatus according to claim 1, wherein each of the light-emitting elements comprises:
a first-type semiconductor layer;
a second-type semiconductor layer;
an active layer disposed between the first-type semiconductor layer and the second-type semiconductor layer;
a plurality of electrodes respectively electrically connected to the first-type semiconductor layer and the second-type semiconductor layer; and
a plurality of conductive bumps respectively electrically connected to the electrodes, wherein a thickness of at least one of the conductive bumps of the second light-emitting element is greater than a thickness of at least one of the conductive bumps of the first light-emitting element.

6. The display apparatus according to claim 1, wherein each of the light-emitting elements comprises:
a first-type semiconductor layer;
a second-type semiconductor layer; and
an active layer disposed between the first-type semiconductor layer and the second-type semiconductor layer,
wherein a thickness of the first-type semiconductor layer of the second light-emitting element is greater than a thickness of the first-type semiconductor layer of the first light-emitting element.

7. The display apparatus according to claim 1, wherein each of the light-emitting elements comprises:
a first-type semiconductor layer;
a second-type semiconductor layer; and
an active layer disposed between the first-type semiconductor layer and the second-type semiconductor layer,
wherein a thickness of the active layer of the second light-emitting element is greater than a thickness of the active layer of the first light-emitting element.

8. The display apparatus according to claim 1, wherein each of the light-emitting elements comprises:
a first-type semiconductor layer;
a second-type semiconductor layer;
an active layer disposed between the first-type semiconductor layer and the second-type semiconductor layer; and
a plurality of electrodes respectively electrically connected to the first-type semiconductor layer and the second-type semiconductor layer, wherein a thickness of at least one of the electrodes of the second light-emitting element is greater than a thickness of at least one of the electrodes of the first light-emitting element.

9. A display apparatus comprising:
a driving backplane comprising:
a substrate;
a plurality of pixel driving circuits disposed on the substrate; and
a pad layer having a plurality of pad sets, wherein the pad sets are respectively electrically connected to the pixel driving circuits; and
a plurality of light-emitting elements respectively electrically connected to the pad sets;
wherein the light-emitting elements comprise a first light-emitting element and a second light-emitting element, the pad sets comprise a first pad set and a second pad set, the first light-emitting element and the second light-emitting element are respectively electrically connected to the first pad set and the second pad set, and a distance between at least one pad of the second pad set and the substrate is greater than a distance between at least one pad of the first pad set and the substrate.

10. The display apparatus according to claim 9, wherein the driving backplane further comprises:
a dielectric layer disposed between the pad layer and the substrate, wherein the dielectric layer comprises a protrusive part overlapping the second light-emitting element and a flat part overlapping the first light-emitting element.

11. The display apparatus according to claim 9, wherein the driving backplane further comprises:
a conductive layer having a plurality of conductive patterns, wherein the conductive patterns are respectively electrically connected to the pixel driving circuits, and the pad sets are respectively electrically connected to the conductive patterns,
wherein the conductive patterns comprise a first conductive pattern and a second conductive pattern, the first pad set and the second pad set are respectively electrically connected to the first conductive pattern and the second conductive pattern, and a distance between the second conductive pattern and the substrate is greater than a distance between the first conductive pattern and the substrate.
